(19) United States
(12) Patent Application Publication
(10) Pub. No.: US 2024/0022038 A1
(43) Pub. Date: Jan. 18, 2024

(54) LASER AMPLIFICATION WITH PASSIVE PEAK-POWER FILTER

(71) Applicant: Electro-Optics Technology, Incorporated, Traverse City, MI (US)

(72) Inventor: Conor BYRNE, Traverse City, MI (US)

(73) Assignee: Electro-Optics Technology, Incorporated, Traverse City, MI (US)

(21) Appl. No.: 18/349,419

(22) Filed: Jul. 10, 2023

Related U.S. Application Data
(60) Provisional application No. 63/389,705, filed on Jul. 15, 2022.

(51) Int. Cl. H01S 3/067; H01S 3/0941; H01S 5/026

(52) U.S. Cl. CPC H01S 3/06783; H01S 3/09415; H01S 5/0265

(57) ABSTRACT

A method for generating amplified laser radiation includes generating a forward-propagating laser beam in a first waveguiding gain stage, amplifying the forward-propagating laser beam in a second waveguiding gain stage, and directing the forward-propagating laser beam from an output waveguide of the first waveguiding gain stage to an input waveguide of the second waveguiding gain stage via a propagation path passing through a Kerr medium. The Kerr medium suppresses coupling, between the first and second waveguiding gain stages, of high-peak-power laser radiation exceeding a threshold intensity in the Kerr medium. Self-focusing in the Kerr medium causes a majority of the high-peak-power laser radiation to be outside at least one of an acceptance aperture and an acceptance angle of a receiving one of the output waveguide of the first waveguiding gain stage and the input waveguide of the second waveguiding gain stage. Each waveguiding gain stage may include a gain fiber.

### CROSS-REFERENCE TO RELATED APPLICATIONS

This application claims the benefit of U.S. Provisional Application No. 63/389,705, filed Jul. 15, 2022, the entire contents of which is incorporated herein by reference.

### TECHNICAL FIELD OF THE DISCLOSURE

The present invention relates to high-power laser systems with two or more sequential stages of gain, and the protection of such laser systems from damage caused by a power spike. The present invention relates in particular to preventing high-power stimulated Brillouin scattering radiation from causing damage in master-oscillator fiber-amplifier systems and multi-stage fiber amplifiers.

### DISCUSSION OF BACKGROUND ART

The gain medium of a fiber laser is an optical fiber. Laser gain is provided by optically-active ions, such as neodymium (Nd³⁺), ytterbium (Yb³⁺), thulium (Tm³⁺), or erbium (Er³⁺), which are doped into the core of the optical fiber and energized by a pump beam. The type of optically-active ion is selected according to the desired output wavelength. For example, neodymium and ytterbium ions provide gain at near-infrared wavelengths, between 1.0 and 1.1 micrometers (μm). Both the pump beam and the generated laser radiation propagate along the length of the optical fiber. The optical fiber prevents beam divergence. It is therefore possible to maintain high optical intensities over a long propagation distance through the gain medium, and thereby achieve a high optical gain in fiber lasers. Similarly, a fiber amplifier utilizes the light confinement of an optical fiber, doped with optically-active ions, to amplify a laser beam with high gain. Amplification by 2-3 orders of magnitude can be achieved. In a fiber laser, the gain fiber is part of a laser resonator. The generated laser radiation makes multiple passes through the optical fiber, and a fraction of the laser radiation is coupled out of the resonator through an output coupler. In a fiber amplifier, on the other hand, the laser beam to be amplified (the “seed beam”) makes a single pass through the gain fiber and is amplified during this single pass.

In a common architecture for high-power fiber laser systems a relatively low-power master oscillator provides “seed” laser radiation, which is amplified by a fiber amplifier or a series of fiber amplifiers. Such master-oscillator fiber-amplifier (MOFA) systems can deliver output laser radiation having an average power greater than 2 kilowatts (kW) in a single longitudinal mode. The master oscillator is typically a fiber laser or wavelength-locked laser diode. It is common to have two or more sequential fiber gain stages in a MOFA system, either in the form of a fiber laser followed by at least one fiber amplifier, or in the form of two or more sequential fiber amplifiers with the first one being seeded by, e.g., a laser diode. The system parameters of each fiber gain stage are selected according to laser power levels of that stage. Typically, the optical fiber dimensions, doping concentration, and pump power for each gain stage are selected to maximize gain while managing nonlinear effects and preventing optical damage to the optical fiber and other fiber components. Additionally, the packaging configuration and materials for the optical fiber and fiber components may be chosen according to the intended laser power levels.

Stimulated Brillouin scattering (SBS) is one nonlinear effect that must be considered in the design of most high-power MOFA systems. SBS stems from the third-order susceptibility χ⁽³⁾ of a material. Fused silica is the most common material for a gain fiber and has a moderate third-order susceptibility χ⁽³⁾ that, in conjunction with high optical intensities and long propagation lengths, can lead to substantial SBS. SBS can cause back reflections that reduce gain efficiency in an optical fiber and limit the output power. SBS can also permanently damage the MOFA system and render it inoperative.

Brillouin scattering occurs when coherent laser radiation generates phonons in the core of an optical fiber. A photon of the forward-propagating laser radiation can generate a phonon and a Stokes-shifted backward-propagating photon, which (a) has lower energy than the forward-propagating photon due to conservation of energy and (b) propagates in the opposite direction due to phase matching. The forward-propagating and backward-propagating radiation can interfere, creating a traveling refractive-index grating by electrostriction. The contrast in this refractive-index grating depends on the degree of temporal coherence imparted onto the backwards-propagating radiation and its intensity.

At low laser intensities, Brillouin scattering occurs only as a spontaneous process and is of relatively little concern. However, the phonon density builds up when forward-propagating laser radiation, having a narrow spectral bandwidth, a long temporal coherence, and sufficient intensity, propagates in an optical fiber of sufficient length. This build-up in the phonon density causes the contrast in the interference-induced refractive-index grating to grow to a level that leads to more Brillouin scattering. At this point, the Brillouin scattering process has become stimulated. The resulting SBS radiation experiences nonlinear gain. In a sufficiently long optical fiber, the intensity of backward-propagating SBS can become comparable to the intensity of the forward-propagating, amplified laser radiation and thus exceed the intensity of the seed laser radiation by up to 2-3 orders of magnitude.

If SBS occurs in the optical fiber of a fiber amplifier, backward-propagating SBS radiation can permanently damage upstream components, such as an optical fiber, a spliced fiber-to-fiber interface, or another fiber component. The damage mechanism is most often local overheating caused by local absorption of the SBS radiation. Optical fiber components of a preceding fiber amplifier or fiber laser are usually most susceptible to damage because the optical fiber components of the preceding fiber amplifier or fiber laser usually are designed for lower power levels. Despite the risks associated with SBS, power requirements can necessitate operating high-power MOFA systems at or near an SBS threshold, i.e., the conditions where Brillouin scattering becomes stimulated rather than spontaneous. Typically, the greatest risk of generating SBS radiation exists in the optical fiber of a last fiber amplifier of the MOFA system.

Techniques for suppressing SBS generation in an optical fiber include increasing the effective mode area of the optical fiber, chemically modifying the fiber-core material, creating temperature gradients along the optical fiber, minimizing the length of the optical fiber by increasing the absorbance of pump radiation, and frequency chirping or spectrally broadening seed laser radiation.

Optical fibers are just one type of waveguide that may be used as a gain medium. Other suitable types of waveguides include planar waveguides and channel waveguides, with one- or two-dimensional waveguiding enabling relatively high optical intensities over a relatively long propagation distance. Even laser diodes, particularly single-mode laser diodes, rely on waveguiding in at least one dimension.

### SUMMARY OF THE DISCLOSURE

Many high-power MOFA systems operate at or near the SBS threshold in at least one fiber amplifier, usually the last one. Although commercial high-power MOFA systems are generally designed and operated to control the risk of SBS radiation reaching problematic levels, SBS radiation occasionally leads to catastrophic failure. In a typical failure scenario, a single pulse of high-intensity, backward-propagating SBS is generated in the optical fiber of a fiber amplifier seeded by another fiber amplifier or fiber laser. The optical fiber, wherein the SBS pulse is generated, can likely withstand the intensity of the SBS pulse. However, optical fibers and fiber components of the preceding fiber amplifier or fiber laser are optimized for significantly lower power levels and may therefore be permanently damaged by the backward-propagating SBS pulse. While SBS suppression techniques exist, these techniques may add too much complexity, be incompatible with other system considerations, or be insufficient to entirely eliminate the risk of catastrophic failure.

Disclosed herein is a passive filtering technique for a MOFA system. This filtering technique utilizes the optical Kerr effect to suppress the coupling of laser radiation between two successive fiber gain stages when a peak-power spike occurs. This technique can be used to, for example, suppress coupling of a backward-propagating SBS pulse into a preceding gain stage. Filtering can be implemented between two successive fiber amplifiers, or between a seed laser (e.g., fiber laser) and a fiber amplifier. The filter itself is entirely passive and responds instantaneously to the peak-power spike, resulting in less downtime than in MOFA systems relying on active, sensor-based protection schemes. The filter may be configured as a free-space optical assembly implemented in a fiber-optic component.

The present filtering technique is not limited to fiber-based systems. More generally, this filtering technique is applicable to laser systems with two or more sequential stages of laser gain in waveguiding gain media, including planar waveguides, channel waveguides, and laser diodes.

In one aspect, a method for generating amplified laser radiation includes generating a forward-propagating laser beam in a first waveguiding gain stage, amplifying the forward-propagating laser beam in a second waveguiding gain stage, and directing the forward-propagating laser beam from an output waveguide of the first waveguiding gain stage to an input waveguide of the second waveguiding gain stage via a propagation path passing through a Kerr medium. The Kerr medium suppresses coupling, between the first and second waveguiding gain stages, of high-peak-power laser radiation exceeding a threshold intensity in the Kerr medium. The coupling is suppressed by self-focusing of the high-peak-power laser radiation in the Kerr medium. The self-focusing causes a majority of the high-peak-power laser radiation to be outside at least one of an acceptance aperture and an acceptance angle of a receiving one of the output waveguide of the first waveguiding gain stage and the input waveguide of the second waveguiding gain stage.

In another aspect, an amplified laser apparatus includes a first waveguiding gain stage for generating a forward-propagating laser beam and a second waveguiding gain stage for amplifying the forward-propagating laser beam. The first waveguiding gain stage includes an output waveguide for emitting the forward-propagating laser beam from the first waveguiding gain stage. The second waveguiding gain stage includes an input waveguide for receiving the forward-propagating laser beam into the second waveguiding gain stage. The amplified laser apparatus further includes a plurality of lenses for coupling the forward-propagating laser beam from the output waveguide of the first waveguiding gain stage into the input waveguide of the second waveguiding gain stage. The lenses include a first lens for collecting the forward-propagating laser beam from the output waveguide, and a second lens for coupling the forward-propagating laser beam into the input waveguide. In addition, the amplified laser apparatus includes a bulk Kerr medium positioned in a propagation path of the forward-propagating laser beam between the first and second lenses such that coupling between the first and second waveguiding gain stages of high-peak-power laser radiation, exceeding an intensity threshold in the bulk Kerr medium, is suppressed by Kerr-induced self-focusing in the bulk Kerr medium.

Any of the aspects and/or features thereof described above or elsewhere herein may be combined in whole or in part with one another.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIG. 1 illustrates an amplified laser apparatus that employs a passive peak-power filtering method, according to an embodiment.

FIG. 2 illustrates acceptance aperture and acceptance angle for an exemplary optical fiber.

FIG. 3 illustrates acceptance aperture and acceptance angle for an exemplary rectangular waveguide.

FIGS. 4A-C illustrate a configuration for passive peak-power filtering between two optical fibers in the apparatus of FIG. 1, with free-space propagation through a bulk Kerr medium, according to an embodiment.

FIGS. 5 and 6 illustrate two respective configurations for passive peak-power filtering between two optical fibers in the apparatus of FIG. 1, with focused free-space propagation through a bulk Kerr medium, according to embodiments.

### DETAILED DESCRIPTION OF THE DISCLOSURE

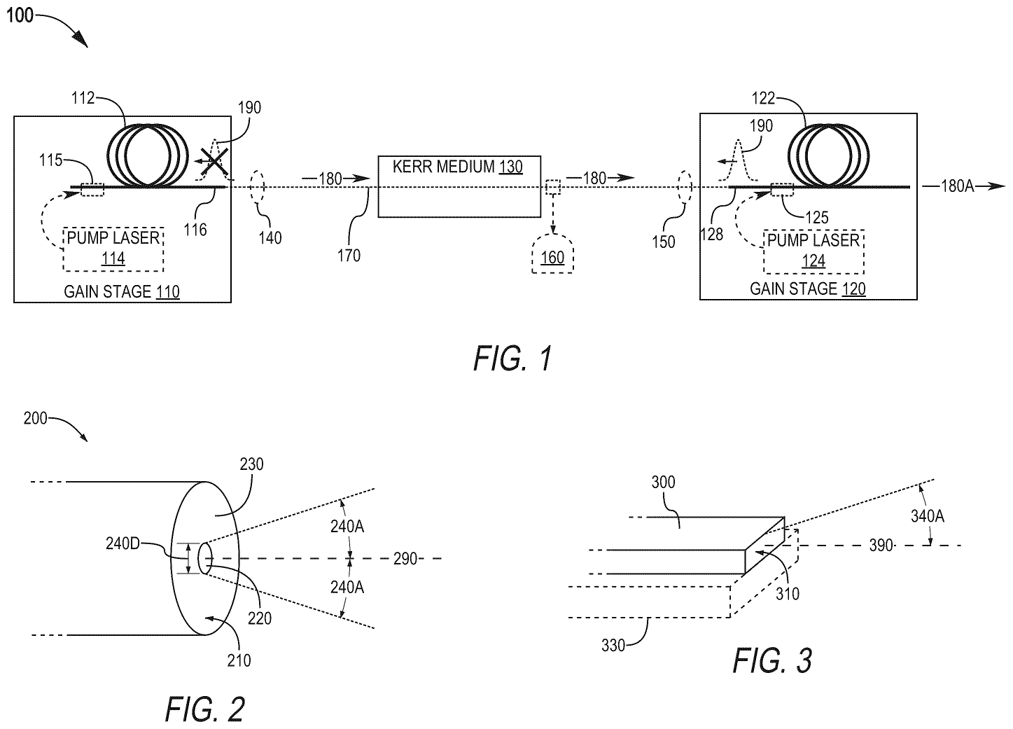

Referring now to the drawings, wherein like components are designated by like numerals, FIG. 1 illustrates one amplified laser apparatus 100 that employs a passive peak-power filtering method. Apparatus 100 includes two fiber gain stages 110 and 120, and a Kerr medium 130 for passive peak-power filtering of laser radiation between gain stages 110 and 120. Gain stage 110 includes a gain fiber 112 that generates forward-propagating laser beam 180, and an output fiber 116. Laser beam 180 emerges from output fiber 116 of gain stage 110 and propagates along a propagation path 170 to gain stage 120. Gain stage 120 includes an input fiber 128 and a gain fiber 122. Gain fiber 122 amplifies laser beam 180, received via input fiber 128, to produce an amplified forward-propagating laser beam 180A. Gain stage 120 may amplify laser beam 180 by a factor of 100 or more. Each of output fiber 116 and input fiber 128 is, for example, a single-mode optical fiber or a large-mode-area optical fiber.

The wavelength of laser beam 180 may be in the near-infrared, visible, or ultraviolet spectral range. Laser beam 180 may be continuous-wave (cw) or pulsed, for example with a pulse duration of 100 picoseconds or more.

Gain stage 110 is a fiber laser or a fiber amplifier. Gain stage 120 is a fiber amplifier. Apparatus 100 may form at least a portion of a MOFA system. Gain stage 110 may include a pump laser 114 that pumps gain fiber 112, and gain stage 120 may include a pump laser 124 that pumps gain fiber 122. Alternatively, gain stages 110 and 120 are configured to receive pump laser light from laser sources obtained elsewhere. Each of gain stages 110 and 120 may include additional fiber components, such as fiber combiners, fiber splitters, fiber-couplers, and additional fibers. For example, gain stage 110 may include a fiber combiner 115 that couples pump laser light from pump laser 114 into gain fiber 112, and gain stage 120 may include a fiber combiner 125 that couples pump laser light from pump laser 124 into gain fiber 122.

Output fiber 116 may be spliced to gain fiber 112, coupled to gain fiber 112 via a fiber-optic component, or otherwise fiber-coupled to gain fiber 112. Alternatively, output fiber 116 may simply be an end-segment of gain fiber 112. Similarly, input fiber 128 may be spliced to gain fiber 122, coupled to gain fiber 122 via a fiber-optic component, or otherwise fiber-coupled to gain fiber 122, or input fiber 128 may be an end-segment of gain fiber 122.

Apparatus 100 also includes “optical coupling elements” that couple laser beam 180 from output fiber 116 of gain stage 110 into input fiber 128 of gain stage 120. Herein, “coupling” of light into an optical fiber (or another type of waveguide) refers to light being coupled into a core mode of the optical fiber (or waveguide). Thus, for the purposes of the present disclosure, light propagating in a cladding mode of an optical fiber (or waveguide) is not considered coupled into the optical fiber (or waveguide). There are numerous different ways to couple light between output fiber 116 and input fiber 128. In certain embodiments, preferrable in many scenarios, output fiber 116 and input fiber 128 are coupled to each other by one or more fiber-optic components, optionally in conjunction with one or more optical fibers. For example, output fiber 116 and input fiber 128 may be coupled to each other via a fiber-optic component that contains a pair of coupling lenses: a lens 140 and a lens 150. Lens 140 collects laser beam 180 from output fiber 116 (or another fiber coupled thereto). At the opposite end of this fiber-optic component, lens 150 couples laser beam 180 into input fiber 128 (or another fiber connected thereto). In other embodiments, apparatus 100 utilizes free-space propagation along propagation path 170 beyond the form of free-space propagation that takes place inside a fiber-optic component. For example, lenses 140 and 150 may be implemented as true free-space components, as opposed to inside a fiber-optic component.

Kerr medium 130 has a non-negligible nonlinear refractive index n₂, due to the optical Kerr effect. The local and instantaneous refractive index in Kerr medium 130 is n=n₀+n₂I, wherein n₀ is the linear refractive index and I is the local optical intensity. Due to the non-negligible nonlinear refractive index n₂, a laser beam passing through Kerr medium 130 will induce a so-called Kerr lens therein, provided that the laser beam has a non-uniform transverse intensity distribution with a higher intensity near the center axis (which is usually the case). A positive Kerr lens is caused by the non-uniform transverse intensity distribution of the laser beam inducing a higher instantaneous refractive index n in the center of the laser beam than in the wings of the beam. The induced Kerr lens has a focusing effect on the laser beam. Since this focusing effect is caused by the laser beam itself, it is a form of “self-focusing”. The degree of self-focusing increases with the intensity of the laser beam. The optical Kerr effect responds instantaneously to the electric field of the laser beam. Therefore, the optical power of the Kerr lens follows the intensity of the laser beam without delay.

FIG. 2 illustrates one optical fiber 200 having an end-face 210, a core 220, and a cladding 230. Light incident on end-face 210 is coupled into optical fiber 200 only if the light is within the acceptance aperture 240D and acceptance angle 240A of optical fiber 200. In the example depicted in FIG. 2, core 220 has a circular cross section, acceptance aperture 240D is a diameter of core 220, and acceptance angle 240A is cylindrically symmetric about a longitudinal axis 290 of core 220.

Accordingly, in the context of apparatus 100, backward-propagating laser radiation incident on output fiber 116 of gain stage 110 and forward-propagating laser radiation incident on input fiber 128 of gain stage 120 is coupled into the respective optical fiber only if incident thereon within the acceptance angle and acceptance aperture of the optical fiber. Single-mode fibers tend to have relatively small acceptance apertures, and light-coupling into a single-mode fiber is therefore quite sensitive to defocusing, pointing errors, and other deviations. Large-mode-area fibers seek to reduce this sensitivity. Certain commercially-available large-mode-area fibers support only a single mode or a few modes and have a larger acceptance aperture than a typical single-mode fiber. In order to limit the number of supported modes, however, this larger acceptance aperture comes at the cost of a smaller acceptance angle. Laser radiation may be incident on output fiber 116 or input fiber 128 from free-space via a coupling lens, such as lens 140 or lens 150. The efficiency of coupling laser radiation from free-space into output fiber 116 or input fiber 128 is determined by the beam parameters and propagation direction of the laser radiation.

During nominal operation of apparatus 100, laser beam 180 emerges from output fiber 116 of gain stage 110, passes through Kerr medium 130, and is coupled into input fiber 128 of gain stage 120. However, more intense laser radiation propagating along propagation path 170 will induce a more powerful Kerr lens and therefore experience stronger self-focusing in Kerr medium 130. When the self-focusing is sufficiently strong, the impact on the beam parameters of the laser radiation suppresses the coupling of laser radiation between gain stages 110 and 120. Kerr medium 130 thus cooperates with one or more of the optical coupling elements of apparatus 100 to function as a passive peak-power filter that (a) turns on instantaneously when the laser radiation intensity in Kerr medium 130 becomes high and (b) turns off instantaneously when the laser radiation intensity drops again.

The dimensions and material composition of Kerr medium 130 are selected such that self-focusing of high-peak-power laser radiation in Kerr medium 130 prevents coupling of the majority of the high-peak-power laser radiation into the receiving one of gain stages 110 and 120. Herein, “high-peak-power laser radiation” refers to laser radiation that exceeds a certain threshold intensity in Kerr medium 130, and “nominal operation” refers to operation in the absence of high-peak-power laser radiation. Self-focusing of high-peak-power laser radiation in Kerr medium 130 may reduce the coupling efficiency from nearly 100% to a few percent or even less than one percent. Laser beam 180 may undergo some degree of self-focusing in Kerr medium 130 during nominal operation. However, this may be accounted for in the optical design of apparatus 100, such that laser beam 180 is coupled into gain stage 120 with the desired coupling efficiency, e.g., 95% or more, during nominal operation. The nonlinear refractive index of Kerr medium 130 may take on a range of values depending on other aspects of apparatus 100 and the power levels of both laser beam 180 and the high-peak-power laser radiation that is intended to be filtered out.

FIG. 1 depicts one passive filtering scenario. In this scenario, gain fiber 122 generates a backward-propagating pulse 190 of high-peak-power laser radiation. Pulse 190 is, for example, a pulse of SBS radiation originating from laser beam 180 during its amplification in gain fiber 122. Pulse 190 undergoes self-focusing in Kerr medium 130, which prevents the majority of pulse 190 from coupling into output fiber 116 of gain stage 110. In one example, laser beam 180 is a continuous-wave beam with an average power of 10 watts (W), pulse 190 has a peak-power of 10 kW, and self-focusing of pulse 190 in Kerr medium 130 suppresses the coupling of pulse 190 into output fiber 116 of gain stage 110 to a coupling efficiency of 1% or less. In this example, the fraction of pulse 190 coupled into gain stage 110 has a peak power of no more than 100 W. The Kerr lens induced by pulse 190 in Kerr medium 130 also affects the beam parameters of laser beam 180. Therefore, while pulse 190 is present in Kerr medium 130, the coupling of laser beam 180 into input fiber 128 of gain stage 120 is suppressed as well. However, as soon as pulse 190 has passed through Kerr medium 130, the laser beam 180 is again coupled into gain stage 120 and nominal coupling efficiency is restored.

In another passive filtering scenario, gain fiber 112 of gain stage 110 generates a forward-propagating pulse of high-peak-power laser radiation, that is, a peak-power spike in laser beam 180. Kerr medium 130 suppresses coupling of this peak-power spike into input fiber 128 of gain stage 120, where amplification of the peak-power spike may otherwise lead to adverse effects. In one example, laser beam 180 is a continuous-wave beam with an average power of 10 W, with an undesirable peak-power spike of 100 W caused by SBS in the forward direction. Self-focusing of the peak-power spike in Kerr medium 130 suppresses coupling of laser beam 180 into input fiber 128 of gain stage 120 to less than 50%, for example 10% or less.

In most situations, the peak power of a forward-propagating SBS pulse generated in gain stage 110 cannot exceed the nominal power of laser beam 180 by as much as the peak power of a backward-propagating SBS pulse generated in gain stage 120, because the backward-propagating SBS pulse originates from laser beam 180 after further amplification in gain fiber 122. This makes it more challenging to filter out forward-propagating SBS pulses with Kerr medium 130. Fortunately, any adverse effects in gain stage 120 caused by a forward-propagating SBS pulse generated in gain stage 110 are usually less detrimental than the adverse effects in gain stage 110 caused by a backward-propagating SBS pulse generated in gain stage 120. In certain embodiments of apparatus 100, the dimensions and material composition of Kerr medium 130 are selected to (a) optimize the transmission of laser beam 180 during nominal operation and (b) limit the coupling of backward-propagating SBS pulses into gain stage 110 to non-damaging power levels. Such embodiments of apparatus 100 may or may not be configured to effectively suppress coupling of forward-propagating SBS pulses into gain stage 120.

Apparatus 100 may further include an active protection system based on one or more sensors 160 that monitor one or more respective power levels in apparatus 100. For example, one sensor 160 may monitor the forward-propagating power in propagation path 170 and generate a control signal (not depicted in FIG. 1) that turns off pump laser 124 when the forward-propagating power stays below a certain level for a certain amount of time. This type of active protection may prevent gain stage 120 from being damaged by a high-power amplified-spontaneous-emission pulse generated while gain fiber 122 is not being seeded by laser beam 180. Another sensor 160 may monitor the backward-propagating power in propagation path 170 and generate a control signal (not depicted in FIG. 1) that turns off both pump laser 114 and pump laser 124 when a pulse 190 of a certain maximum amplitude or minimum duration is detected, so as to prevent gain stages 110 and 120 from being damaged. However, the response time of active protection systems is limited at least by the transmission and processing speeds of electrical signals in electronic circuitry, both when acting to shut down operation and when acting to resume operation. The response time of active protection systems is therefore significantly longer than that of the passive filtering mechanism provided by Kerr medium 130. The instantaneous response of the passive filtering mechanism provided by Kerr medium 130 can thus reduce downtime in MOFA systems caused by peak-power spikes.

Apparatus 100 may include additional gain stages, not shown in FIG. 1. Passive peak-power filtering, effected by Kerr medium 130, may be implemented between each pair of successive gain stages. However, peak-power spikes propagating backwards from the last gain stage of a MOFA system are usually of greater concern than peak-power spikes generated in earlier gain stages in a MOFA system. It may therefore be sufficient, and most cost-effective, to include Kerr medium 130 between the last pair of gain stages.

Apparatus 100 and the passive filtering method based on Kerr medium 130 are readily extended to other forms of optical waveguides than optical fibers. These optical waveguides may provide light confinement in one or two transverse dimensions. Thus, more generally, each of gain stages 110 and 120 may be replaced by a respective waveguiding gain stage, wherein gain fibers 112 and 122 are replaced by respective gain waveguides. Output fiber 116 may be replaced by an output waveguide, and input fiber 128 may be replaced by an input waveguide. Suitable types of waveguides include planar waveguides and channel waveguides. A planar waveguide has a rectangular cross section. One dimension of the rectangular cross section is relatively small, for example a fraction of a millimeter, and confines one transverse dimension of light propagating through the waveguide. A channel waveguide also has a rectangular cross section but with both dimensions of the rectangular cross section confining light propagating through the waveguide. Both the planar waveguide and the channel waveguide may be (mostly) surrounded by air or disposed on, or embedded in, a substrate having a lower refractive index than the waveguide itself.

FIG. 3 shows one waveguide 300, with a rectangular cross section, that may be implemented in gain stage 110 and/or 120. Waveguide 300 has a rectangular end-face 310. Waveguide 300 may be disposed on a substrate 330, as depicted in FIG. 3, or embedded in substrate 330 (not shown in FIG. 3). Waveguide 300 has an acceptance aperture, which is end-face 310, and an acceptance angle 340A for light coupling. Acceptance angle 340A may or may not be cylindrically symmetric about the longitudinal axis 390 of waveguide 300. When waveguide 300 is implemented in place of output fiber 116 of gain stage 110 and in place of input fiber 128 of gain stage 120, backward-propagating laser radiation incident on gain stage 110 and forward-propagating laser radiation incident on gain stage 120 is coupled into the respective output/input waveguide only if incident thereon within the acceptance angle and acceptance aperture of the waveguide.

Hereinafter, apparatus 100 and the associated passive peak-power filtering method are discussed in the context of optical fibers. The discussed embodiments are readily extendable to other types of waveguides.

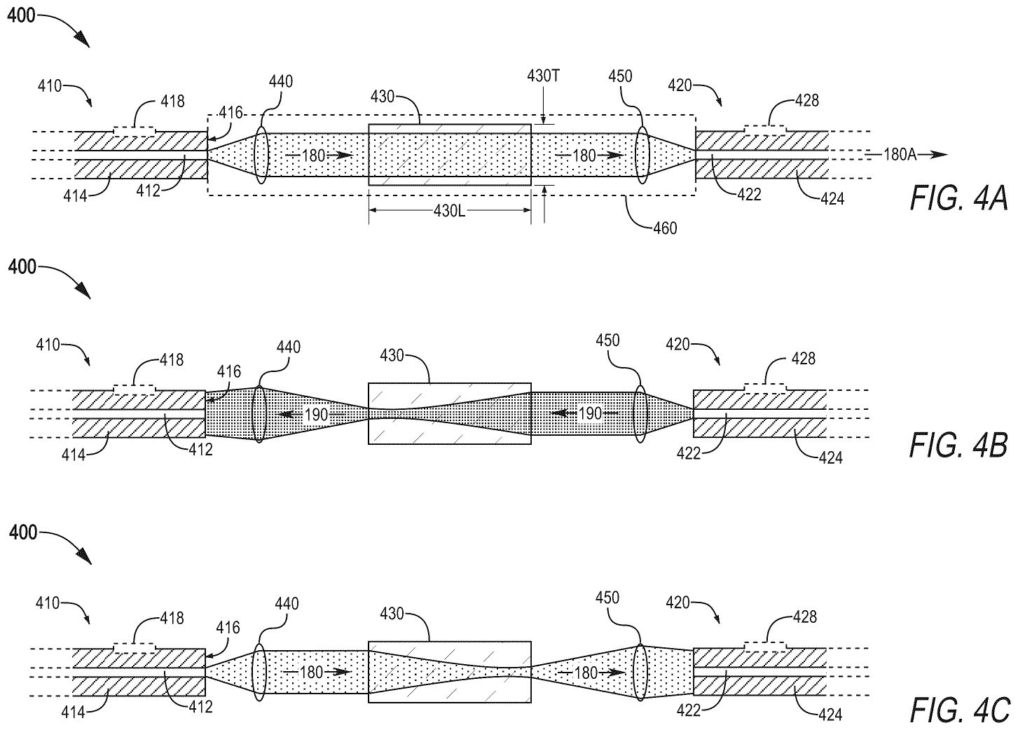

FIGS. 4A-4C illustrate one configuration 400 for passive peak-power filtering between two optical fibers in apparatus 100, with free-space propagation through a bulk Kerr medium 430. Bulk Kerr medium 430 is an embodiment of Kerr medium 130, and configuration 400 is applicable to apparatus 100. FIG. 4A shows exemplary propagation of laser beam 180 during nominal operation. FIG. 4B shows exemplary propagation of pulse 190 of backward-propagating high-peak-power laser radiation. FIG. 4C shows exemplary forward propagation of laser beam 180 during the presence of backward-propagating pulse 190.

During nominal operation in configuration 400, as shown in FIG. 4A, laser beam 180 emerges from a core 412 of an optical fiber 410, is collected by a lens 440, passes through bulk Kerr medium 430, and is coupled into a core 422 of optical fiber 420. Optical fiber 410 may be output fiber 116 of gain stage 110 or an optical fiber that is fiber-coupled to output fiber 116. Alternatively, optical fiber 410 may be another optical fiber positioned in the path of laser beam 180 between output fiber 116 and bulk Kerr medium 430. Similarly, optical fiber 420 may be input fiber 128 of gain stage 120, an optical fiber that is fiber-coupled to input fiber 128, or another optical fiber positioned in the path of laser beam 180 between bulk Kerr medium 430 and input fiber 128. Lenses 440 and 450 are examples of lenses 140 and 150, respectively.

Coupling of laser radiation between optical fibers 410 and 420 is sensitive to the beam parameters of the laser radiation. In turn, the beam parameters are sensitive to Kerr lensing in bulk Kerr medium 430. As shown in FIG. 4B, self-focusing of pulse 190 in bulk Kerr medium 430 causes the majority of pulse 190 to be outside the acceptance aperture and/or acceptance angle of optical fiber 410. In a more extreme case, some of pulse 190 may miss end-face 416 entirely. Most likely, a significant fraction of pulse 190 propagates in a cladding mode of optical fiber 410. Although less intense than if propagating in a core mode, such a cladding-mode fraction of pulse 190 may still have adverse effects. It may therefore be advantageous to remove this fraction of pulse 190 from optical fiber 410. For this purpose, optical fiber 410 may have a mode-stripping feature 418 that leaks out light propagating in cladding modes. Mode-stripping feature 418 may be a surface texture on cladding 414 or a material deposited on the surface of cladding 414. Cladding-mode propagation may also be at least partly prevented by a physical aperture (not shown in FIGS. 4A-C) between lens 440 and end-face 416.

While pulse 190 is present in bulk Kerr medium 430, laser beam 180 is also subject to focusing by the Kerr lens induced by pulse 190. This is illustrated schematically in FIG. 4C, where the Kerr lens is shown to suppress coupling of laser beam 180 into optical fiber 420. Optical fiber 420 may include a mode-stripping feature 428 that leaks out light propagating in cladding modes.

The dimensions of bulk Kerr medium 430 may be compatible with implementation in a standard fiber component package. For example, as a fiber-optic component 460 together with lenses 440 and 450. For example, bulk Kerr medium 430 may be a rod or block with a length 430L that is less than 20 millimeters (mm) and a maximum transverse dimension 430T that is less than 5 mm. Fiber-optic component 460 connects optical fibers 410 and 420 to each other and contains lens 440, bulk Kerr medium 430, and lens 450. Bulk Kerr medium 430 and lenses 440 and 450 are aligned within fiber-optic component 460 to ensure proper optical alignment with optical fibers 410 and 420.

The optimal value of length 430L depends at least on the material of bulk Kerr medium 430 and its nonlinear refractive index, as well as on the nominal power of laser beam 180 and the maximum peak power that may be allowed to couple between gain stages 110 and 120. Bulk Kerr medium 430 may have a nonlinear refractive index of at least 10⁻²⁰ m²/W at the operating wavelength of apparatus 100. In one such example, bulk Kerr medium 430 is made of fused silica and has a length 430L in the range between 10 and 30 mm. The nonlinear refractive index of fused silica is 2.2×10⁻²⁰ m²/W at a wavelength of around 1 micrometer (μm). A smaller length 430L may suffice if Kerr medium 430 is made of a material with a higher nonlinear refractive index, such as zinc selenide, which has a nonlinear refractive index of 430×10⁻²⁰ m²/W at a wavelength of around 1 μm.

Beam parameters should be considered as well when choosing the material and dimensions of bulk Kerr medium 430. In the example depicted in FIG. 4A, laser beam 180 is nominally collimated in bulk Kerr medium 430. At the location where a peak-power spike, such as pulse 190, is incident on bulk Kerr medium 430, the caustic of the peak-power spike is usually similar to the nominal caustic of laser beam 180. In the FIG. 4A example, laser beam 180 is nominally collimated between lenses 440 and 450, and pulse 190 of FIG. 4B is therefore likely to collimated when incident on bulk Kerr medium 430. Depending on the power level of the peak-power spike and the properties of bulk Kerr medium 430, it may be necessary to focus the laser radiation within bulk Kerr medium 430 in order to induce the degree of self-focusing required to achieve a desired filtering performance.

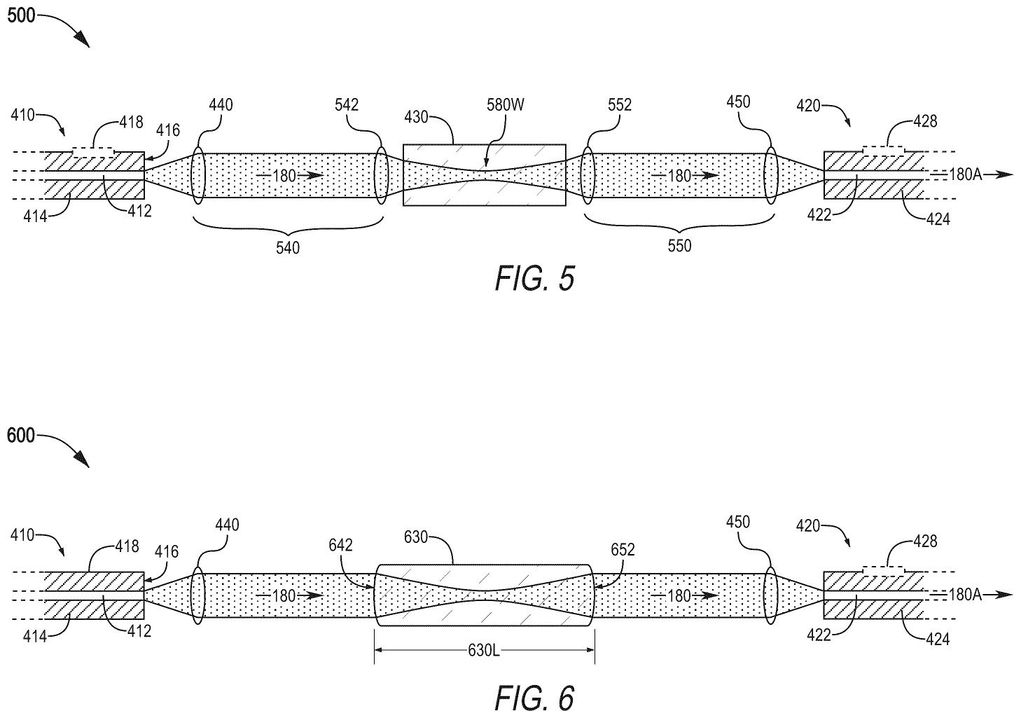

FIG. 5 illustrates one configuration 500 for passive peak-power filtering between two optical fibers in apparatus 100, with focused free-space propagation through bulk Kerr medium 430. Configuration 500 includes two telescopes 540 and 550 that serve to achieve higher laser beam intensities in bulk Kerr medium 430 so as to produce stronger Kerr lensing. Configuration 500 is similar to configuration 400 except for including additional lenses 542 and 552. Lens 542 cooperates with lens 440 to form telescope 540 that focuses laser beam 180 to a waist 580W in bulk Kerr medium 430, during nominal operation. In one example, the diameter of waist 580W is in the range between 10 and 50 μm. Lens 552 cooperates with lens 450 to form telescope 550 that, during nominal operation, couples laser beam 180 into optical fiber 420. Telescope 550 also focuses backward-propagating laser radiation, emerging from optical fiber 420, in bulk Kerr medium 430. As shown in FIG. 5, lens 440 may be configured to collimate laser beam 180, and lens 552 may be configured to re-collimate laser beam 180, during nominal operation.

FIG. 6 illustrates another configuration 600 for passive peak-power filtering between two optical fibers in apparatus 100, with focused free-space propagation through a bulk Kerr medium. Configuration 600 may be viewed as a modification of configuration 500 wherein bulk Kerr medium 430 and lenses 542 and 552 are replaced by a bulk Kerr medium 630 with convex end-faces 642 and 652. Convex end-face 642 has the same function as lens 542, and convex end-face 652 has the same function as lens 552. Configuration 600 integrates the focusing effects of lenses 542 and 552 into the bulk Kerr medium and thereby eliminates two optical elements. In configuration 600, lens 440 may be configured to collimate laser beam 180, and convex end-face 652 may be configured to re-collimate laser beam 180, during nominal operation.

The performance of one example of configuration 600 was evaluated by modeling. The model considered an example of bulk Kerr medium 630 made of fused silica, having a length 630L of 17 mm, and characterized by a 2.7 mm radius of curvature of each of convex end-faces 642 and 652. The model assumed that laser beam 180 is collimated between coupling lens 440 and bulk Kerr medium 630 as well as between bulk Kerr medium 630 and coupling lens 450, during nominal operation. The model demonstrated effective suppression of coupling of laser radiation between optical fibers 410 and 420 when the peak power was increased to 20 kW from a nominal value of 20 W.

The present invention is described above in terms of a preferred embodiment and other embodiments. The invention is not limited, however, to the embodiments described and depicted herein. Rather, the invention is limited only by the claims appended hereto.

What is claimed is:

1. A method for generating amplified laser radiation, comprising steps of:
generating a forward-propagating laser beam in a first waveguiding gain stage;
amplifying the forward-propagating laser beam in a second waveguiding gain stage; and
directing the forward-propagating laser beam from an output waveguide of the first waveguiding gain stage to an input waveguide of the second waveguiding gain stage via a propagation path passing through a Kerr medium that suppresses coupling, between the first and second waveguiding gain stages, of high-peak-power laser radiation exceeding a threshold intensity in the Kerr medium, wherein the coupling is suppressed by self-focusing of the high-peak-power laser radiation in the Kerr medium, the self-focusing causing a majority of the high-peak-power laser radiation to be outside at least one of an acceptance aperture and an acceptance angle of a receiving one of the output waveguide of the first waveguiding gain stage and the input waveguide of the second waveguiding gain stage.

2. The method of claim 1, wherein the high-peak-power laser radiation is backward-propagating stimulated Brillouin scattering radiation generated in the second waveguiding gain stage, and the self-focusing suppresses coupling of the backward-propagating stimulated Brillouin scattering radiation into the output waveguide of the first waveguiding gain stage.

3. The method of claim 1, wherein the high-peak-power laser radiation is forward-propagating stimulated Brillouin scattering radiation generated in the first waveguiding gain stage, and the self-focusing suppresses coupling of the forward-propagating stimulated Brillouin scattering radiation into the input waveguide of the second waveguiding gain stage.

4. The method of claim 1, wherein the propagation path passes through free space between the output waveguide of the first waveguiding gain stage and the Kerr medium and between the Kerr medium and input waveguide of the second waveguiding gain stage.

5. The method of claim 4, wherein the directing step includes focusing the forward-propagating laser beam to a waist inside the Kerr medium.

6. An amplified laser apparatus, comprising:
a first waveguiding gain stage for generating a forward-propagating laser beam including an output waveguide for emitting the forward-propagating laser beam from the first waveguiding gain stage;
a second waveguiding gain stage for amplifying the forward-propagating laser beam including an input waveguide for receiving the forward-propagating laser beam into the second waveguiding gain stage;
a plurality of lenses for coupling the forward-propagating laser beam from the output waveguide of the first waveguiding gain stage into the input waveguide of the second waveguiding gain stage, the lenses including
a first lens for collecting the forward-propagating laser beam from the output waveguide, and
a second lens for coupling the forward-propagating laser beam into the input waveguide; and
a bulk Kerr medium positioned in a propagation path of the forward-propagating laser beam between the first and second lenses such that coupling between the first and second waveguiding gain stages of high-peak-power laser radiation, exceeding an intensity threshold in the bulk Kerr medium, is suppressed by Kerr-induced self-focusing in the bulk Kerr medium.

7. The amplified laser apparatus of claim 6, wherein the bulk Kerr medium has first and second convex end-faces intersecting the propagation path, respectively.

8. The amplified laser apparatus of claim 7, wherein the first lens is configured to collimate the forward-propagating laser beam, the first convex end-face is configured to produce a waist in the forward-propagating laser beam inside the bulk Kerr medium, and the second convex end-face is configured to re-collimate the forward-propagating laser beam.

9. The amplified laser apparatus of claim 6, wherein the plurality of lenses is arranged such that the forward-propagating laser beam, at least in the absence of the high-peak-power laser radiation, has a waist in the bulk Kerr medium.

10. The amplified laser apparatus of claim 9, wherein the plurality of lenses further includes third and fourth lenses, the third lens cooperating with the first lens to form a telescope between the output waveguide of the first waveguiding gain stage and the bulk Kerr medium, the fourth lens cooperating with the second lens to form a telescope between the bulk Kerr medium and the input waveguide of the second waveguiding gain stage.

11. The amplified laser apparatus of claim 6, wherein the plurality of lenses and the bulk Kerr medium are implemented in a fiber-optic component.

12. The amplified laser apparatus of claim 6, wherein each of the output waveguide and the input waveguide is an optical fiber, and wherein each of the first and second waveguiding gain stages includes a gain fiber.

13. A master-oscillator fiber-amplifier system, comprising:
a first fiber gain stage for generating a forward-propagating laser beam, the forward-propagating laser beam being continuous-wave, the first fiber gain stage including an output fiber for emitting the forward-propagating laser beam from the first fiber gain stage, the output fiber having an acceptance aperture and acceptance angle with respect to coupling of backward-propagating radiation into the output fiber;
a second fiber gain stage for amplifying the forward-propagating laser beam, the second fiber gain stage including an input fiber for receiving the forward-propagating laser beam into the second fiber gain stage;
a plurality of lenses for coupling the forward-propagating laser beam from the output fiber of the first fiber gain stage into the input fiber of the second fiber gain stage, the lenses including
a first lens for collecting the forward-propagating laser beam from the output fiber, and
a second lens for coupling the forward-propagating laser beam into the input fiber; and
a bulk Kerr medium for suppressing coupling, into the first fiber gain stage, of a backward-propagating pulse of high-peak-power laser radiation generated in the second fiber gain stage, the bulk Kerr medium being positioned in a propagation path of the forward-propagating laser beam between the first and second lenses such that the backward-propagating pulse undergoes Kerr-induced self-focusing in the bulk Kerr medium, the self-focusing causing a majority of the backward-propagating pulse to be outside at least one of the acceptance aperture and the acceptance angle of the output fiber of the first fiber gain stage.

14. The master-oscillator fiber-amplifier system of claim 13, wherein the backward-propagating pulse contains stimulated Brillouin scattering radiation.

15. The master-oscillator fiber-amplifier system of claim 13, wherein the bulk Kerr medium has first and second convex end-faces intersecting the propagation path, respectively.

16. The master-oscillator fiber-amplifier system of claim 15, wherein the first lens is configured to collimate the forward-propagating laser beam, the first convex end-face is configured to produce a waist in the forward-propagating laser beam inside the bulk Kerr medium, and the second convex end-face is configured to re-collimate the forward-propagating laser beam.

17. The master-oscillator fiber-amplifier system of claim 13, wherein the plurality of lenses is arranged such that the forward-propagating laser beam, at least in the absence of high-peak-power laser radiation, has a waist in the bulk Kerr medium.

18. The master-oscillator fiber-amplifier system of claim 17, wherein the plurality of lenses further includes third and fourth lenses, the third lens cooperating with the first lens to form a telescope between the output fiber of the first fiber gain stage and the bulk Kerr medium, the fourth lens cooperating with the second lens to form a telescope between the bulk Kerr medium and the input fiber of the second fiber gain stage.

19. The master-oscillator fiber-amplifier system of claim 13, wherein the plurality of lenses and the bulk Kerr medium are implemented in a fiber-optic component.
